(19) United States
(12) Patent Application Publication
(10) Pub. No.: US 2003/0141991 A1
(43) Pub. Date: Jul. 31, 2003

(54) Design of a computer keyboard eliminating the mouse as a separate entity

(76) Inventor: Santosh S. Honnavalli, Palo Alto, CA (US)

Correspondence Address: SANTOSH S. HONNAVALLI, 3351 ALMA ST, #204, PALO ALTO, CA, 94306, US

(21) Appl. No.: 10/057,148

(22) Filed: Jan. 28, 2002

(51) Int. Cl. H03K 17/94; H03M 11/00

(52) U.S. Cl. 341/22

(57) ABSTRACT

As the usage of computers increase in our daily lives, the hazards of keyboard and mouse usage also have increased proportionately. This new keyboard design is an effort to reduce the damage caused to the hand. The main feature of this design is the integration of keyboard and mouse into a single board in a very user-friendly way leaving the current functionality completely intact. Also, an alternative to mouse clicks has been provided via the usage of keys. Elimination of a peripheral device may be cost effective as well.

### CROSS-REFERENCE TO RELATED APPLICATIONS

Zagnoev, Ari—U.S Pat. No. 5,936,555

Retter; Dale J—U.S. Pat. No. 4,917,516

Solhjell, Erk—U.S. Pat. No. 5,621,436

Franz; Patrick J—U.S. Pat. No. 5,568,987

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

It is a well-known fact that persistent use of desktop computer keyboard and mouse combination causes severe damage to hand. A lot of effort has gone into designing mouse of various shapes and sizes, retaining mouse as a separate physical entity. These designs still put all the stress on the index and middle fingers from essentially the same wrist position and angle. The wrist still has to operate the mouse away from the keyboard constantly switching between the two. In cases where the mouse functionality is designed within the keyboard itself like a pointing stick, the ease of operation necessary for constant usage is completely absent and emphasis is laid mainly on cursor movement without regard to the crucial mouse functionalities like double clicks and cursor drags. Also, considerable retraining would be needed due to the change in relative key positions.

### BRIEF SUMMARY OF THE INVENTION

This desktop keyboard design eliminates the need for a separate mouse, incorporating all the mouse functionalities within it in a very user-friendly manner. Keys are provided to replace mouse clicks and mouse drags relieving the fingers of a lot of stress. Since the wrist would always be in the typing position, stress on it is greatly reduced. Also, no retraining would be necessary, as all the currently existing key groups would remain unchanged. Various mechanisms could be devised for cursor movement retaining essentially the same idea.

### BRIEF DESCRIPTION OF THE SEVERAL VIEWS OF THE DRAWING

FIG. 1A represents the Top View of the Keyboard highlighting only the new additions to the already existing widely used keyboards. Gray portions indicate additions and boxes indicate the already existing key groups.

FIG. 1B represents the Side View of the Keyboard showing only the new additions.

FIG. 2 represents the Top View of the Keyboard for an alternate design retaining the same basic idea.

### DETAILED DESCRIPTION OF THE INVENTION

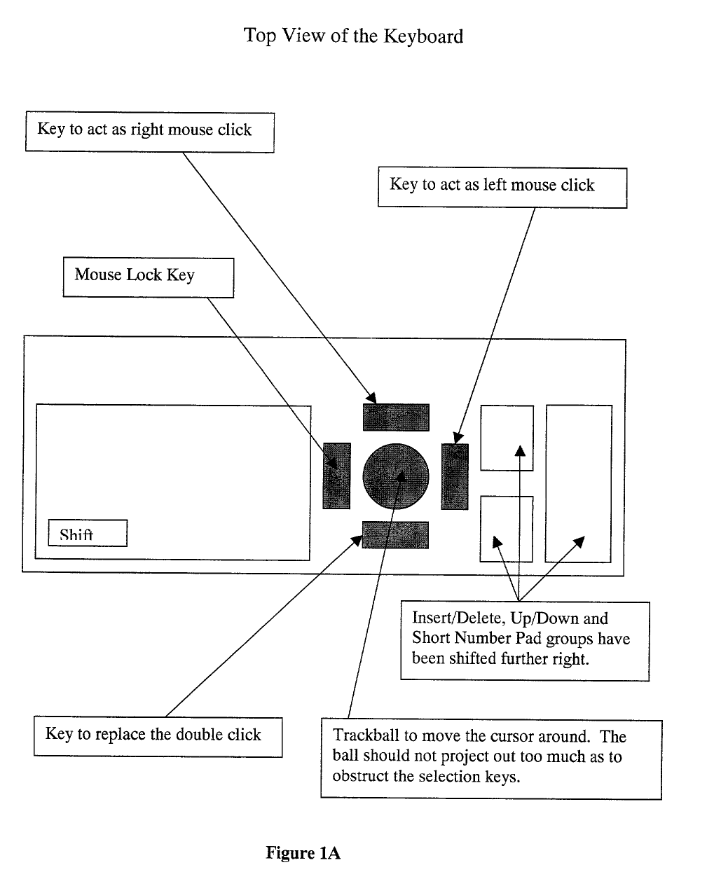

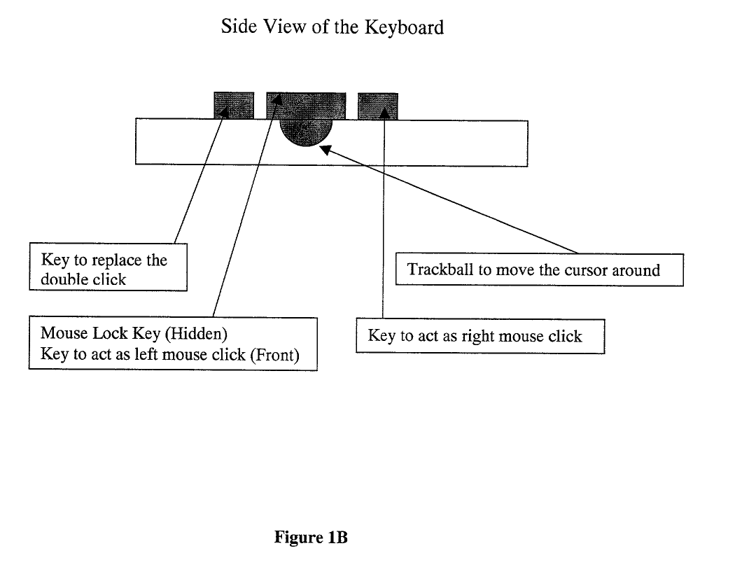

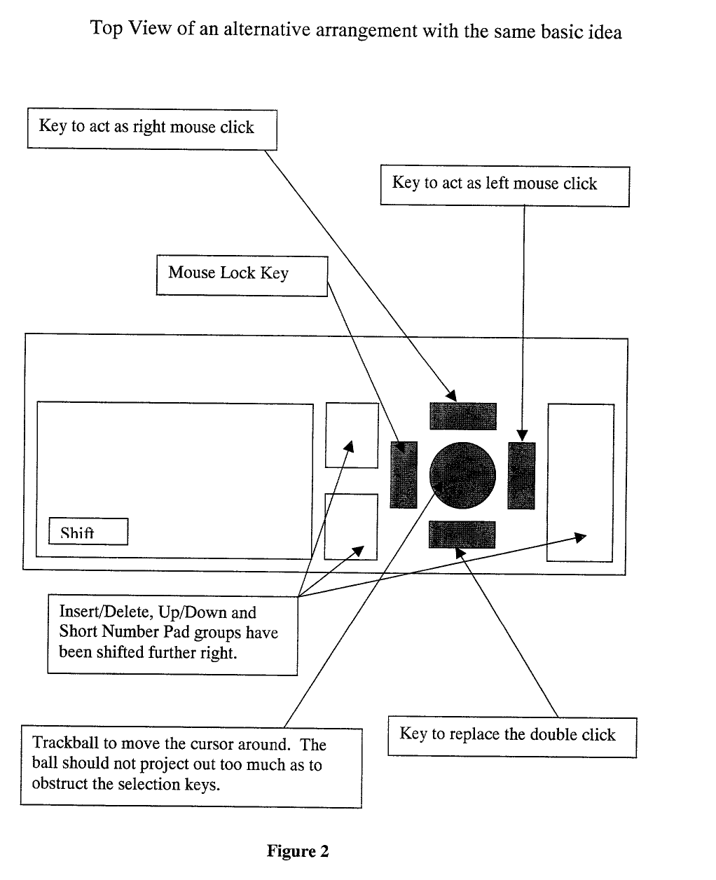

The mechanical design for the proposed desktop keyboard is shown in FIG. 1A and FIG. 1B. All the keys in a standard keyboard are retained. Also, the relative positions of all the keys within a group would remain unchanged but the three groups of keys to the right of the main block is shifted further right to accommodate the items shown in gray, preferably with the mouse selection keys placed relative to the trackball as shown in FIG. 1A. This is to allow easy access to keys related to the mouse that are used most frequently. The placement of these keys may be moved around but always in the vicinity of the trackball. But the crucial thing is that a key would represent the double click—there is no need to actually double click. The cursor movements are controlled using the trackball. In cases where there is a need to drag the cursor as opposed to just moving it, Mouse Lock key should be used. This situation occurs often enough during interactions with Graphical User Interface elements like resizing, moving windows or drag and drop files. This key toggles with itself. Also, any of the mouse selection keys would release the lock. The surface of the ball should ideally be at the same height as all other keys so as to not obscure them. The diameter of the ball should be about 1 inch. An alternative arrangement would be to move only the current rightmost group further right to accommodate the new items as shown in FIG. 2. For people who prefer to use left hand, the new additions could be accommodated leftmost of the keyboard. The way the new keys and trackball would provide the currently existing mouse functionality is outlined below.

Left, right, double click—Respective keys.

Word selection—Double click key.

Paragraph selection—Mouse Lock, trackball movement, and any mouse click key. The same effect could be achieved using the existing Shift and the new mouse click selection keys.

Cursor drag—Mouse Lock and Trackball.

Cursor movement—Trackball.

What I claim as my invention is:

1. The design of a very user-friendly desktop keyboard integrating all the mouse functionalities within it and at the same time leaving the existing key groups completely untouched.

2. The provision of an alternative to mouse clicks, double-clicks and mouse drags via convenient mouse specific keys.
